(19) United States
(12) Patent Application Publication
(10) Pub. No.: US 2023/0387160 A1
(43) Pub. Date: Nov. 30, 2023

(54) PIXEL WITH DIFFRACTIVE SCATTERING GRATING AND HIGH COLOR RESOLUTION ASSIGNING SIGNAL PROCESSING

(71) Applicant: SONY SEMICONDUCTOR SOLUTIONS CORPORATION, Kanagawa (JP)

(72) Inventor: Victor A. Lenchenkov, Rochester, NY (US)

(73) Assignee: SONY SEMICONDUCTOR SOLUTIONS CORPORATION, Kanagawa (JP)

(21) Appl. No.: 17/752,586

(22) Filed: May 24, 2022

(51) Int. Cl. H01L 27/146; G02B 5/18

(52) U.S. Cl. CPC H01L 27/14625; H01L 27/1462; H01L 27/14645; G02B 5/1842; G02B 5/1814

(57) ABSTRACT

Color image sensors and systems are provided. A color image sensor as disclosed includes a plurality of pixels disposed within an array, each of which includes a plurality of sub-pixels. A diffraction layer is disposed adjacent a light incident surface side of the array of pixels. The diffraction layer provides a set of transparent diffraction features for each pixel. The diffraction features focus and diffract light onto the sub-pixels of the respective pixel. Color information regarding light incident on a pixel is determined by comparing ratios of signals between pairs of sub-pixels to a calibration table containing ratios of signals determined using incident light at a number of different, known wavelengths. A wavelength with signal ratios that result in a smallest difference as compared to the observed set of signal ratios is assigned as a color of the light incident on the pixel.

### FIELD

The present disclosure relates to an imaging device incorporating a diffractive grating to enable high color resolution and sensitivity.

### BACKGROUND

Digital image sensors are commonly used in a variety of electronic devices, such as hand held cameras, security systems, telephones, computers, and tablets, to capture images. In a typical arrangement, light sensitive areas or pixels are arranged in a two-dimensional array having multiple rows and columns of pixels. Each pixel generates an electrical charge in response to receiving photons as a result of being exposed to incident light. For example, each pixel can include a photodiode that generates charge in an amount that is generally proportional to the amount of light (i.e. the number of photons) incident on the pixel during an exposure period. The charge can then be read out from each of the pixels, for example through peripheral circuitry.

In conventional color image sensors, absorptive color filters are used to enable the image sensor to detect the color of incident light. The color filters are typically disposed in sets (e.g. of red, green, and blue (RGB); cyan, magenta, and yellow (CMY); or red, green, blue, and infrared (RGBIR)). Such arrangements have about 3-4 times lower sensitivity and signal to noise ratio (SNR) at low light conditions, color cross-talk, color shading at high chief ray angles (CRA), and lower spatial resolution due to color filter patterning resulting in lower spatial frequency as compared to monochrome sensors without color filters. However, the image information provided by a monochrome sensor does not include information about the color of the imaged object.

In addition, conventional color and monochrome image sensors incorporate non-complementary metal-oxide semiconductor (CMOS), polymer-based materials, for example to form filters and micro lenses for each of the pixels, that result in image sensor fabrication processes that are more time-consuming and expensive than processes that only require CMOS materials. Moreover, the resulting devices suffer from compromised reliability and operational life, as the included color filters and micro lenses are subject to weathering and performance that degrades at a much faster rate than inorganic CMOS materials. In addition, the processing required to interpolate between pixels of different colors in order to produce a continuous image is significant.

Image sensors have been developed that utilize uniform, non-focusing metal gratings, to diffract light in a wavelength dependent manner, before that light is absorbed in a silicon substrate. Such an approach enables the wavelength characteristics (i.e. the color) of incident light to be determined, without requiring the use of absorptive filters. However, the non-focusing diffractive grating results in light loss before the light reaches the substrate. Such an approach also requires an adjustment or shift in the microlens and the grating position and structures across the image plane to accommodate high chief ray angles (CRAs).

Accordingly, it would be desirable to provide an image sensor with high sensitivity and high color resolution that could be produced more easily than previous devices.

### SUMMARY

Embodiments of the present disclosure provide image sensors, image sensing methods, and methods for producing image sensors that provide high color resolution and sensitivity. An image sensor in accordance with embodiments of the present disclosure includes a sensor substrate having a plurality of pixels. Each pixel in the plurality of pixels includes a plurality of sub-pixels. A diffraction layer is disposed adjacent a light incident surface side of the image sensor. The diffraction layer includes a set of transparent diffraction elements or features for each pixel in the plurality of pixels. The diffraction features operate to focus and diffract incident light onto the sub-pixels. The diffraction pattern produced across the area of the pixel by the diffraction features is dependent on the color or wavelength of the incident light. As a result, the color of the light incident on a pixel can be determined from ratios of relative signal intensities at each of the sub-pixels within the pixel. Accordingly, embodiments of the present disclosure provide a color image sensor that does not require color filters. In addition, embodiments of the present disclosure do not require micro lenses or infrared filters in order to provide high resolution images and high resolution color identification. The resulting color image sensor thus has high sensitivity, high spatial resolution, high color resolution, wide spectral range, a low stack height, and can be manufactured using conventional CMOS processes.

An imaging device or apparatus in accordance with embodiments of the present disclosure incorporates an image sensor having a diffraction layer on a light incident side of a sensor substrate. The sensor substrate includes an array of pixels, each of which includes a plurality of light sensitive areas or sub-pixels. The diffraction layer includes a set of transparent diffraction features for each pixel. The diffraction features can be configured to focus the incident light by providing a higher effective index of refraction towards a center of an associated pixel, and a lower effective index of refraction towards a periphery of the associated pixel. For example, a density or proportion of a light incident area of a pixel covered by the diffraction features can be higher at or near the center of the pixel than it is towards the periphery. Moreover, the set of diffraction features associated with at least some of the pixels can be asymmetric relative to a center of the pixel. Accordingly, the diffraction features operate as diffractive pixel micro lenses, which create asymmetric diffractive light patterns that are strongly dependent on the color and spectrum of incident light. Because the diffraction layer is relatively thin (e.g. about 500 nm or less), it provides a very high coherence degree for the incident light, which facilitates the formation of stable interference patterns.

The relative distribution of the incident light amongst the sub-pixels of a pixel is determined by comparing the signal ratios. For example, in a configuration in which each pixel includes a 2×2 array of sub-pixels, there are 6 possible combinations of sub-pixel signal ratios that can be used to identify the color of light incident at the pixel with very high accuracy. In particular, because the interference pattern produced by the diffraction elements strongly correlates with the color and spectrum of the incident light, the incident light color can be identified with very high accuracy (e.g. within 25 nm or less). The identification or assignment of the color of the incident light from the ratios of signals produced by the sub-pixels can be determined by comparing those ratios to pre-calibrated subpixel photodiode signal ratios (attributes) of the color spectrum of incident light. The total signal of the pixel is calculated as a sum of all of the subpixel signals. A display or output of the identified color spectrum can be produced by converting the determined color of the incident light into RGB space.

An imaging device or apparatus incorporating an image sensor in accordance with embodiments of the present disclosure can include an imaging lens that focuses collected light onto an image sensor. The light from the lens is focused and diffracted onto pixels included in the image sensor by transparent diffraction features. More particularly, each pixel includes a plurality of sub-pixels, and is associated with a set of diffraction features. The diffraction features function to create an asymmetrical diffraction pattern across the sub-pixels. Differences in the strength of the signals at each of the sub-pixels within a pixel can be applied to determine a color (i.e. a wavelength) of the light incident on the pixel.

Imaging sensing methods in accordance with embodiments of the present disclosure include focusing light collected from within a scene onto an image sensor having a plurality of pixels disposed in an array. The light incident on each pixel is focused and diffracted by a set of diffraction features onto a plurality of included sub-pixels. The diffraction pattern produced by the diffraction features depends on the color or spectrum of the incident light. Accordingly, the amplitude of the signal generated by the incident light at each of the sub-pixels in each pixel can be read to determine the color of that incident light. In accordance with embodiments of the present disclosure, the assignment of a color to light incident on a pixel includes determining ratios of signal strengths produced by sub-pixels within the pixel, and comparing those ratios to values stored in a lookup table for color assignment. The amplitude or intensity of the light incident on the pixel is the sum of all of the signals from the sub-pixels included in that pixel. An image sensor produced in accordance with embodiments of the present disclosure therefore does not require micro lenses for each pixel or color filters, and provides high sensitivity over a range that can be coincident with the full wavelength sensitivity of the image sensor pixels.

Methods for producing an image sensor in accordance with embodiments of the present disclosure include applying conventional CMOS production processes to produce an array of pixels in an image sensor substrate in which each pixel includes a plurality of sub-pixels or photodiodes. As an example, the material of the sensor substrate is silicon (Si), and each sub-pixel is a photodiode formed therein. A thin layer of material is disposed on or adjacent a light incident side of the image sensor substrate. Moreover, the thin layer of material can be disposed on a back surface side of the image sensor substrate. As an example, the thin layer of material is silicon oxide (SiO₂), and has a thickness of 500 nm or less. In accordance with the least some embodiments of the present disclosure, an anti-reflection layer can be disposed between the light incident surface of the image sensor substrate and the thin layer of material. A light focusing, transparent scattering diffractive grating pattern is formed in the thin layer of material. In particular, a set of diffraction features is disposed adjacent each of the pixels. The diffraction features can be formed as relatively high index of refraction features embedded in the thin layer of material. For example, the diffraction features can be formed from silicon nitride (SiN). Moreover, the diffraction features can be relatively thin (i.e. from about 100 to about 200 nm), and the pattern can include a plurality of lines of various lengths disposed asymmetrically about a central circular feature. Notably, production of an image sensor in accordance with embodiments of the present disclosure can be accomplished using only CMOS processes. Moreover, an image sensor produced in accordance with embodiments of the present disclosure does not require micro lenses or color filters for each pixel.

Additional features and advantages of embodiments of the present disclosure will become more readily apparent from the following description, particularly when considered together with the accompanying drawings.

### BRIEF DESCRIPTION OF THE DRAWINGS

FIG. 1 depicts elements of a color sensing image sensor in accordance with embodiments of the present disclosure;

FIG. 2 is a plan view of a portion of an exemplary color sensing image sensor in accordance with the prior art;

FIG. 3 is a cross section of a portion of an exemplary color sensing image sensor in accordance with the prior art;

FIG. 4 is a graph depicting the sensitivity to light of different wavelengths of an examplary image sensor in accordance with the prior art;

FIG. 5 depicts components of a system incorporating a color sensing image sensor in accordance with embodiments of the present disclosure;

FIG. 6 is a perspective view of a pixel included in a color sensing image sensor in accordance with embodiments of the present disclosure;

FIGS. 7A-7F are plan views of example pixel configurations in accordance with embodiments of the present disclosure;

FIGS. 8A-8B are cross sections in elevation of pixel configurations in accordance with embodiments of the present disclosure;

FIGS. 9A-9B depict the diffraction of light by a set of diffractive elements across the sub-pixels of a pixel included in a color sensing image sensor in accordance with embodiments of the present disclosure;

FIG. 10 depicts a distribution of light of a selected wavelength across the sub-pixels of a pixel included in a color sensing image sensor in accordance with embodiments of the present disclosure, and an example set of resulting sub-pixel pair signal ratios;

FIG. 11 depicts distributions of light of different wavelengths across the sub-pixels of a pixel included in a color sensing image sensor in accordance with embodiments of the present disclosure;

FIG. 12 depicts a table of signal ratio values for different wavelengths of light incident on the sub-pixels of an example pixel in accordance with embodiments of the present disclosure;

FIG. 13 depicts aspects of a process for acquiring and applying a set of measured signal ratios to a table of signal ratio values for different wavelengths of light to determine a wavelength of light incident on an example pixel in accordance with embodiments of the present disclosure;

FIG. 14 depicts an exemplary set of measured signal ratios and a table of calculated difference values in accordance with embodiments of the present disclosure; and

FIG. 15 is a block diagram illustrating a schematic configuration example of a camera that is an example of an image sensor in accordance with embodiments of the present disclosure.

### DETAILED DESCRIPTION

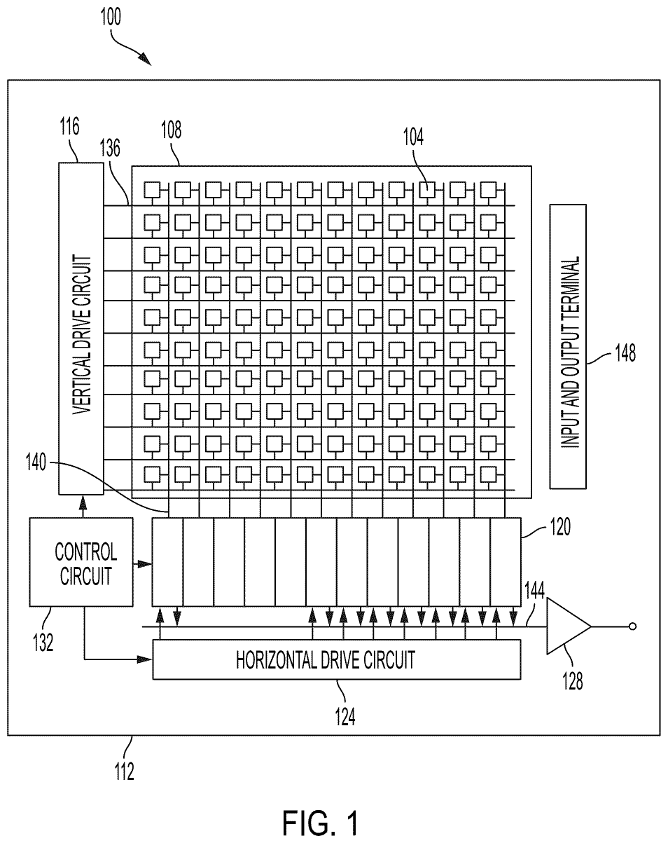

FIG. 1 is a diagram that depicts elements of a color sensing image sensor or device 100 in accordance with embodiments of the present disclosure. In general, the color sensing image sensor 100 includes a plurality of pixels 104 disposed in an array 108. More particularly, the pixels 104 can be disposed within an array 108 having a plurality of rows and columns of pixels 104. Moreover, the pixels 104 are formed in an imaging or semiconductor substrate 112. In addition, one or more peripheral or other circuits can be formed in connection with the imaging substrate 112. Examples of such circuits include a vertical drive circuit 116, a column signal processing circuit 120, a horizontal drive circuit 124, an output circuit 128, and a control circuit 132. As described in greater detail elsewhere herein, each of the pixels 104 within a color sensing image sensor 100 in accordance with embodiments of the present disclosure includes a plurality of photosensitive sites or sub-pixels.

The control circuit 132 can receive data for instructing an input clock, an operation mode, and the like, and can output data such as internal information related to the image sensor 100. Accordingly, the control circuit 132 can generate a clock signal that provides a standard for operation of the vertical drive circuit 116, the column signal processing circuit 120, and the horizontal drive circuit 124, and control signals based on a vertical synchronization signal, a horizontal synchronization signal, and a master clock. The control circuit 132 outputs the generated clock signal in the control signals to the various other circuits and components.

The vertical drive circuit 116 can, for example, be configured with a shift register, can operate to select a pixel drive wiring 136, and can supply pulses for driving sub-pixels of a pixel 104 through the selected drive wiring 136 in units of a row. The vertical drive circuit 116 can also selectively and sequentially scan elements of the array 108 in units of a row in a vertical direction, and supply the signals generated within the pixels 104 according to an amount of light they have received to the column signal processing circuit 120 through a vertical signal line 140.

The column signal processing circuit 120 can operate to perform signal processing, such as noise removal, on the signal output from the pixels 104. For example, the column signal processing circuit 120 can perform signal processing such as a correlated double sampling (CDS) for removing a specific fixed patterned noise of a selected pixel 104 and an analog to digital (A/D) conversion of the signal.

The horizontal drive circuit 124 can include a shift register. The horizontal drive circuit 124 can select each column signal processing circuit 120 in order by sequentially outputting horizontal scanning pulses, causing each column signal processing circuit 122 to output a pixel signal to a horizontal signal line 144.

The output circuit 128 can perform predetermined signal processing with respect to the signals sequentially supplied from each column signal processing circuit 120 through the horizontal signal line 144. For example, the output circuit 128 can perform a buffering, black level adjustment, column variation correction, various digital signal processing, and other signal processing procedures. An input and output terminal 148 exchanges signals between the image sensor 100 and external components or systems.

Accordingly, a color sensing image sensor 100 in accordance with at least some embodiments of the present disclosure can be configured as a CMOS image sensor of a column A/D type in which column signal processing is performed.

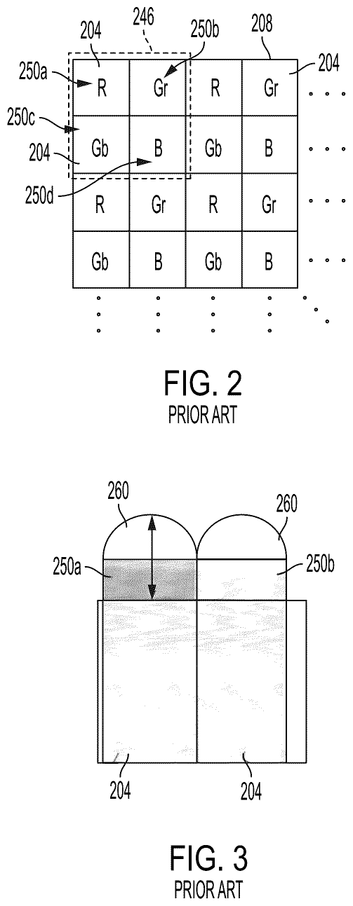

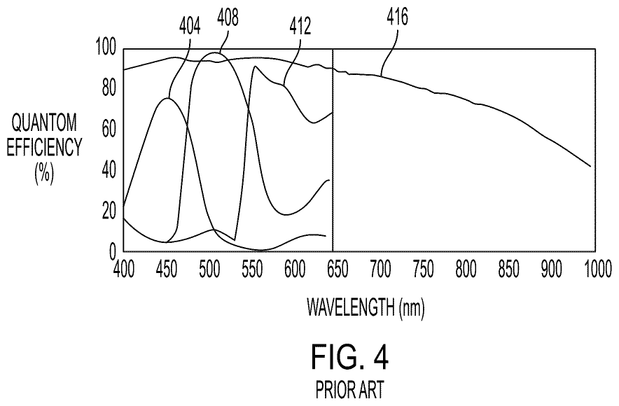

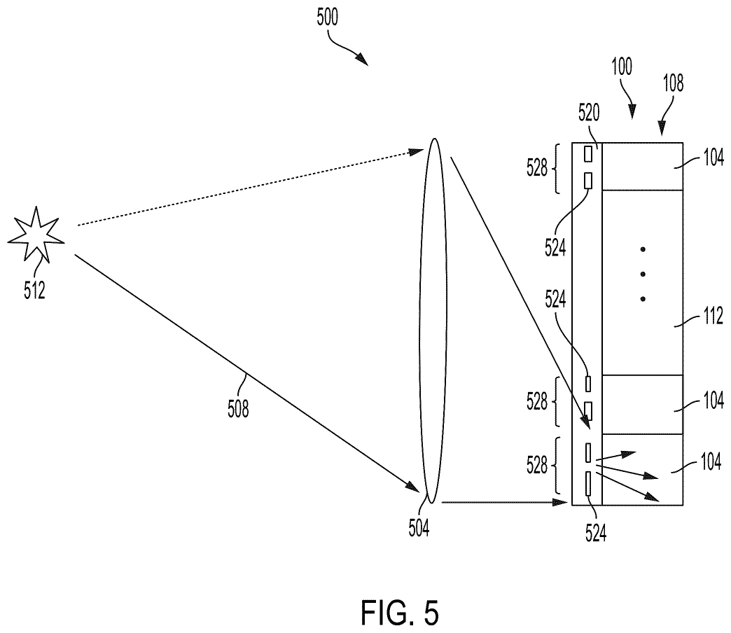

With reference now to FIGS. 2 and 3, portions of a pixel array 208 of an exemplary color sensing image sensor in accordance with the prior art are depicted. FIG. 2 shows a portion of the pixel array 208 in a plan view, and illustrates how individual pixels 204 are disposed in 2×2 sets 246 of four pixels 204. In this particular example, each 2×2 set 246 of four pixels 204 is configured as a so-called Bayer array, in which a first one of the pixels 204 is associated with a red color filter 250a, a second one of the pixels 204 is associated with a green color filter 250b, a third one of the pixels 204 is associated with another green color filter 250c, and fourth one of the pixels 204 is associated with the blue color filter 250d. FIG. 3 illustrates a portion of the pixel 204 encompassing one such Bayer array in cross section. In such a configuration, each individual pixel 204 is only sensitive to a portion of the visible spectrum. As a result, the spatial resolution of the image sensor is reduced as compared to monochrome sensors. Moreover, because the light incident on the photosensitive portion of each pixel 204 is filtered, sensitivity is lost. This is illustrated in FIG. 4, which includes lines 404, 408, and 412, corresponding to the sensitivity of pixels associated with blue, green and red filters 250 respectively, and also with an infrared-cut filter. The sensitivity of a monochrome sensor that is not associated with any filters is shown at line 416. In addition to the various performance issues, conventional color and monochrome image sensors have a relatively high stack height, and typically incorporate non-CMOS polymer-based materials, which adds costs to the manufacturing process, and results in a device that is less reliable and that has a shorter lifetime, as color filters and micro lenses are subject to weathering and to performance that degrades more quickly than inorganic CMOS materials.

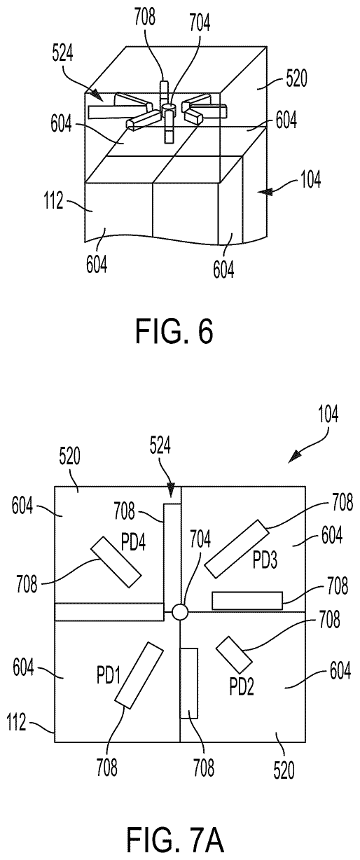

FIG. 5 depicts components of a system 500 incorporating a color sensing image sensor 100 in accordance with embodiments of the present disclosure. As shown, the system 500 can include an optical system 504 that collects and focuses light from within a field of view of the system 500, including light 508 reflected or otherwise received from an object 512 within the field of view of the system 500, onto the pixel array 108 of the image sensor 100. As can be appreciated by one of skill in the art after consideration of the present disclosure, the optical system 504 can include a number of lenses, apertures, shutters, filters or other elements. In accordance with embodiments of the present disclosure, the pixel array 108 includes an imaging or sensor substrate 112 in which the pixels 104 of the array 108 are formed. In addition, a diffraction layer 520 is disposed on a light incident surface side of the substrate 112, between the pixel array 108 and the optical system 504. The diffraction layer 520 includes a plurality of transparent diffraction features or elements 524. More particularly, the diffraction features or elements 524 are provided as sets 528 of diffraction features 524, with one set 528 of diffraction features 524 being provided for each pixel 104 of the array 108.

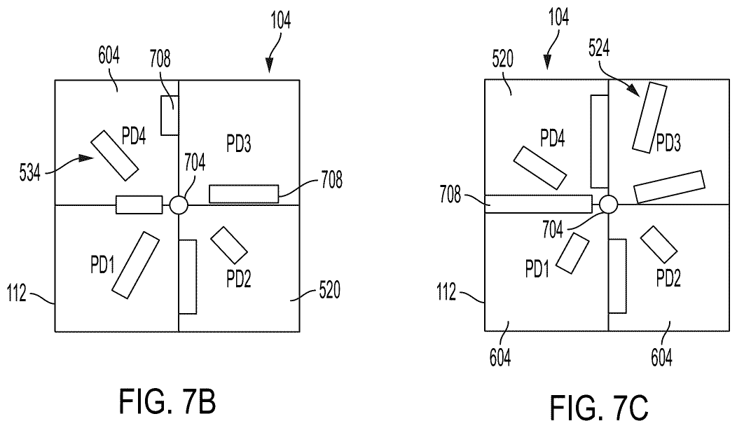

With reference now to FIGS. 6-8, configurations of a color sensing image sensor 100 in accordance with embodiments of the present disclosure with respect to individual pixels 104 and included sub-pixels 604, and associated diffraction features 524, are depicted. More particularly,

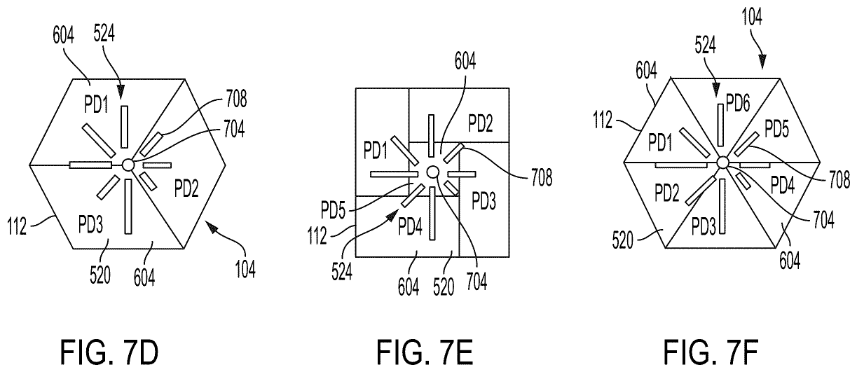

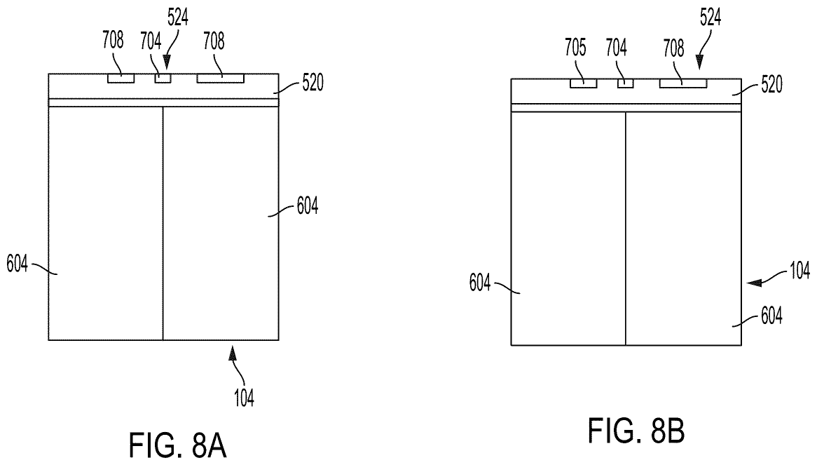

FIG. 6 is a perspective view of a pixel 104 included in a color sensing image sensor in accordance with embodiments of the present disclosure; FIGS. 7A-F are plan views of pixels 104 having different example diffraction feature 524 or sub-pixel 604 configurations in accordance with embodiments of the present disclosure; and FIGS. 8A and 8B are cross sections in elevation of pixels 104 in accordance with embodiments of the present disclosure having different diffraction feature 524 configurations.

The sub-pixels 604 within a pixel 104 generally include adjacent photoelectric conversion elements or areas within the image sensor substrate 112. In operation, each sub-pixel 604 generates a signal in proportion to an amount of light incident thereon. As an example, each sub-pixel 604 is a photodiode. As represented in FIGS. 6, 7A, 7B, 7C, 8A, and 8B, each pixel 104 can include four sub-pixels 604, with each of the sub-pixels 604 having an equally sized, square-shaped light incident surface. However, embodiments of the present disclosure are not limited to such a configuration, and can instead have any number of sub-pixels 604, with each of the sub-pixels 604 having the same or different shape, and/or the same or different size, as other sub-pixels 604 within the pixel 104. For example, each pixel 104 can include three sub-pixels 604 of the same size and a quadrilateral shape, placed together to form a pixel 104 having a hexagonal shape (FIG. 7D); each pixel 104 can be comprised of five sub-pixels 604 having different sizes and shapes (FIG. 7E); or each pixel 104 can be comprised of six sub-pixels 604 having the same size and a triangular shape pieced together to form a pixel 104 with a hexagonal shape (FIG. 7F). In accordance with still other embodiments of the present disclosure, different pixels 104 can have different shapes sizes and configurations of included sub-pixels 604.

The diffraction features 524 are generally centered in or about the pixel 104 area, and in particular the area of the light incident surface of the pixel 104. In accordance with the least some embodiments of the present disclosure, the set of diffraction features 524 associated with a pixel 104 include a central feature 704, and a number of elongated elements 708 in an area adjacent the respective pixel 104 and around the central feature 704. The central feature 704 can be implemented as a disc or circular element, while the elongated elements 708 can include linear elements, some or all of which being disposed on or along lines that extend radially from the central feature 704. Accordingly, the elongated elements can be radially disposed about the central feature 704. Moreover, the central feature 704 can be located at the geometric center of the light incident area of a pixel 104. In accordance with further embodiments of the present disclosure, the central feature 704 can be located along a line extending from the geometric center of the light incident surface of the pixel at an angle corresponding to a chief ray angle of the pixel 104 when that pixel is incorporated into a particular system 500.

Different diffraction feature 524 patterns or configurations can be associated with different pixels 104 within an image sensor 100. For example, each pixel 104 can be associated with a different pattern of diffraction features 524. As another example, a particular diffraction feature 524 pattern 524 can be used for all of the pixels 104 within all or selected regions of the array 108. As a further example, differences in diffraction feature 524 patterns can be distributed about the pixels 104 of an image sensor randomly. Alternatively or in addition, different diffraction feature 524 patterns can be selected so as to provide different focusing or diffraction characteristics at different locations within the array 108 of pixels 104. For instance, aspects of a diffraction feature 524 pattern can be altered based on a distance of a pixel associated with the pattern from a center of the array 108.

Examples of different diffraction feature or element 524 configurations are depicted in FIGS. 7A, 7B, and 7C, in which pixels 104 having the same sub-pixel 604 configuration are associated with diffraction features or elements 524 having different dimensions, numbers of diffraction elements, and/or positions of diffraction elements. In accordance with embodiments of the present disclosure, the diffraction features 524 associated with any one pixel 104 are disposed asymmetrically about a center point of that pixel 104. The asymmetry can be apparent in at least one of a plan view, for example in the length and/or width of the longitudinal elements 708, in a cross-sectional view (as shown in FIG. 8B, in which the depth of different diffraction features 524 differs), or in a refractive index of the diffraction features 524. In accordance with still further embodiments of the present disclosure, the locations of the diffraction features 524 within the diffraction layer 520 can be varied.

In accordance with at least some embodiments of the present disclosure, the diffraction features 524 are transparent, and have a higher index of refraction than the material of the surrounding diffraction layer 520. As an example, but without limitation, the material of the diffraction layer 520 can have an index of refraction of less than 1.5 and the diffraction features 524 can have an index of refraction of 2 or more. As specific examples, the diffraction layer 520 can be formed of low index SiO2, having a refractive index (n) that is about equal to 1.46, where about is ±10%, and the diffraction features 524 can be formed with a transparent higher refractive index material, such as SiN, TiO₂, HfO₂, Ta₂O₅, or SiC, with an index of refraction of from about 2 to about 2.6. The diffraction features 524 are relatively thin. For example, the central feature 704 can be a disk with a radius of from about 50 to about 100 nm, while the elongated elements 708 can have a width of from about 50 to about 100 nm and a length of from about 100 nm to more than half a width of an associated pixel 104 area. The diffraction features 524 can extend into the diffraction layer 520 by an amount that is a fraction (e.g. less than half) of the thickness of the diffraction layer 520. For example, for a diffraction layer 520 that is about 500 nm thick, the diffraction features 524 formed therein can have a thickness of from about 150-200 nm. As an example, the diffraction features 524 can be formed from trenches in the diffraction layer 520 that are filled with material having a higher index of refraction than the diffraction layer 520 material.

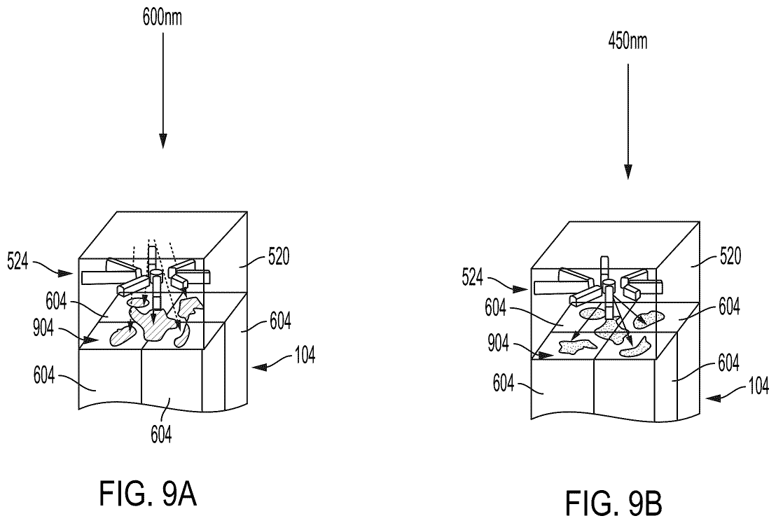

As can be appreciated by one of skill in the art after consideration of the present disclosure, a diffraction grating or feature diffracts light of different wavelengths by different amounts. FIGS. 9A and 9B depict the different diffraction patterns 904 produced by a set of diffraction features 524 of a pixel 104 in a color sensing image sensor 100 in accordance with embodiments of the present disclosure in response to receiving different wavelengths of incident light 508. In FIG. 9A, a distribution pattern 904 produced on a surface of a pixel 104 by a set of associated diffraction features 524 by incident light 508 having a wavelength of 600 nm (i.e. red light) is depicted. In FIG. 9B, a distribution pattern 904 produced on a surface of the same pixel 104 and set of associated diffraction features 524 by incident light 508 having a wavelength of 450 nm (i.e. blue light) is depicted.

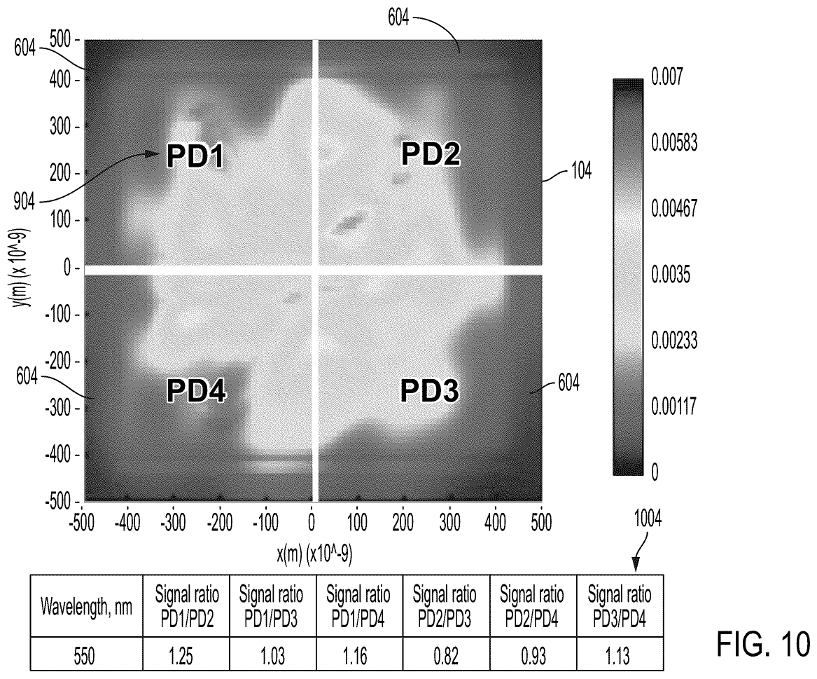

In accordance with embodiments of the present disclosure, the different distributions 904 of different colored light across the different sub-pixels 604 of a pixel 104 allows the color of the light incident of the pixel 104 to be determined. In particular, the differences in the amount of light incident on the different sub-pixels 604 results in the generation of different signal amounts by those sub-pixels 604. This is illustrated in FIG. 10, which depicts an example distribution of light 904 having a selected wavelength across the sub-pixels 604 of a pixel 104 included in a color sensing image sensor 100 in accordance with embodiments of the present disclosure, and a set of resulting sub-pixel 604 pair signal ratios 1004. As can be appreciated by one of skill in the art after consideration of the present disclosure, taking the ratios of the signals from each unique pair of sub-pixels 604 within a pixel 104 allows the distribution pattern 904 to be characterized consistently, even when the intensity of the incident light varies. Moreover, this simplifies the determination of the color associated with the detected distribution pattern 904 by producing normalized values. Thus, the example set of signal ratios for the 550 nm light in the example table of FIG. 10 applies for any intensity of incident light.

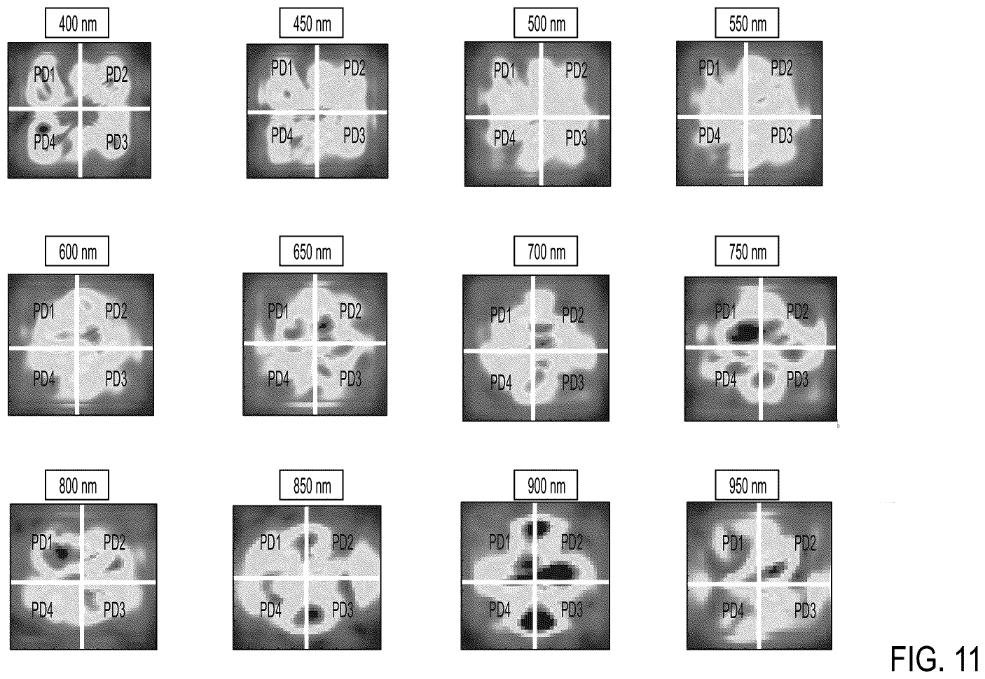

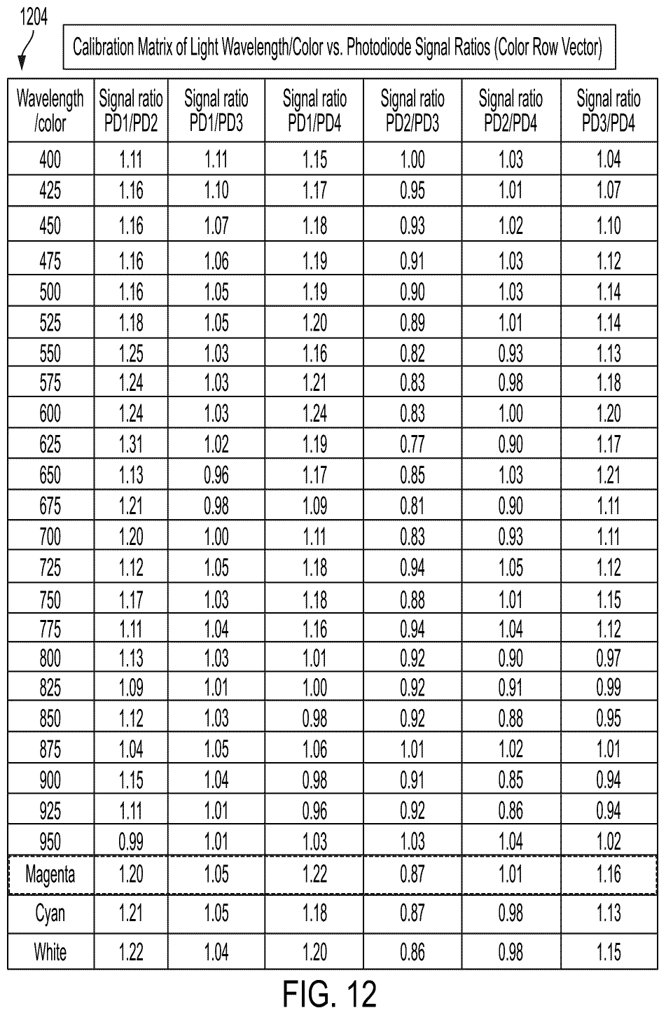

Embodiments of the present disclosure also provide for relatively high color resolution. In particular, as depicted in FIG. 11, differences in the distribution of light of different wavelengths across the sub-pixels 604 of a pixel by a given pattern of distribution features 524 can be distinguished for relatively narrow wavelength differences. More particularly, FIG. 11 depicts different interference patterns produced by different wavelengths of light by a given pattern of diffraction features 524. The different light intensities at the different sub-pixels 604 will in turn result in the generation of different signal amplitudes by the different sub-pixels 604. As illustrated in FIG. 12, the ratios of the signal strength between different pairs of sub-pixels 604 for each of the different patterns produced by different selected wavelengths can be represented in a table, referred to herein as a calibration table 1204. Moreover, the ratios of the signals at the sub-pixels 604 for light at different wavelengths can be determined at relatively small intervals. For example, the signals produced at the sub-pixels 604 of a pixel 204 can be recorded for a series of wavelengths separated from one another by 25 nm. In accordance with still further embodiments of the present disclosure, signals at the sub-pixels 604 for even smaller wavelength intervals can be stored in the calibration table 1204, to enable even finer wavelength determinations. Conversely, where less color precision is required, larger wavelength intervals (e.g. 50 nm or 100 nm) can be calibrated and stored. Accordingly, by identifying a wavelength in a table of different wavelengths associated with subpixel 604 signal strengths that most closely matches the ratio of signal strengths observed for a sample of light of an unknown wavelength, that wavelength or color can be accurately assigned. Moreover, identification of the wavelength of the incident light is possible across a wide range of wavelengths. For example, identification of any wavelength to which the sub-pixels 604 are sensitive is possible. For instance, wavelengths over a range of from 400 nm to 1000 nm are possible. In accordance with embodiments of the present disclosure, an identification of the color of the light incident on a pixel 104 is performed using a simple analytical expression:

Color ID=Abs(1.1*PD1/PD2−1.2*PD1/PD3+1.3*PD1/PD4−1.4*PD2/PD3+1.5*PD2/PD4−1.6*PD3/PD4)

As shown in the example calibration table 1204, the calibrated color identification can be stored in a column of color (wavelength) identification values. The amplitude or intensity of the signal at the pixel 104 is the sum of the subpixel 604 values. As can be appreciated by one of skill in the art after consideration of the present disclosure, the values within the table 1204 are provided for illustration purposes, and actual values will depend on the particular configuration of the diffraction features 524 and other characteristics of the pixel 104 and associated components of the image sensor 100 as implemented.

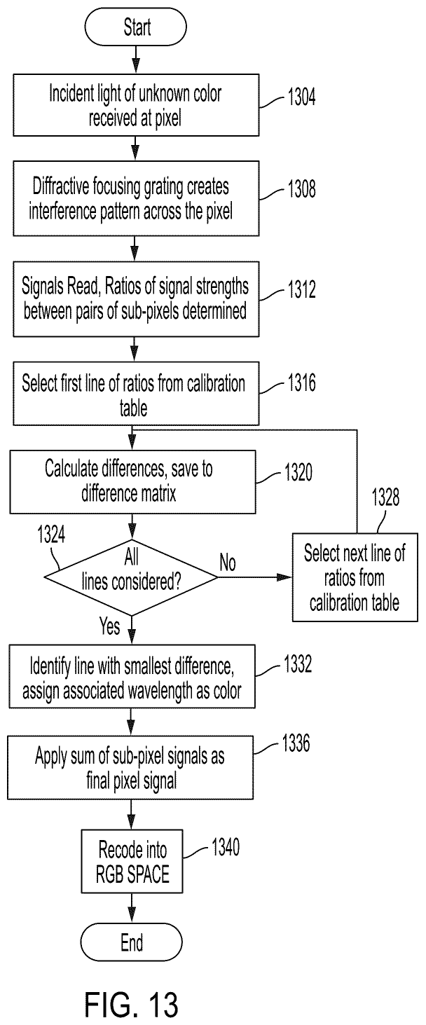

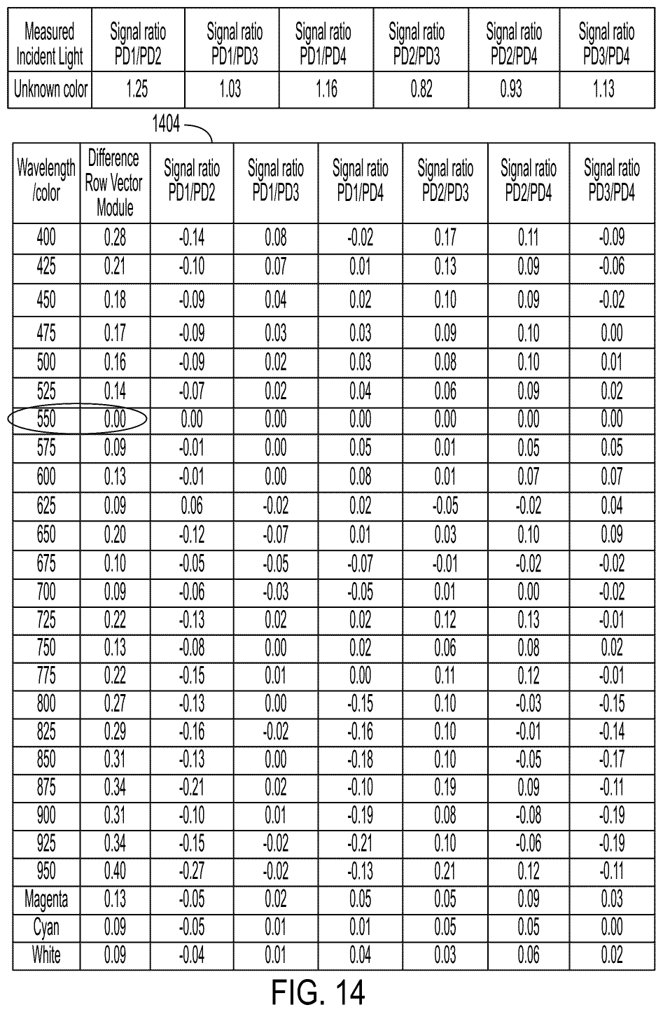

FIG. 13 depicts aspects of a process for assigning and applying a set of measured signal ratios to a calibration table containing signal ratio values for different wavelengths of light to determine a wavelength of light incident on an example pixel 104. Initially, at step 1304, incident light of an unknown color is received in an area of an image sensor 100 corresponding to a pixel 104. The set 528 of diffractive focusing features 524 associated with the pixel 104 creates an interference pattern across the sub-pixels 604 of the pixel 104 (step 1308). The signals generated by the sub-pixels 604 in response to receiving the incident light are read out, and the ratios of signal strength between pairs of the sub-pixels 604 are determined (step 1312). In particular, the ratio of the signal strength between the two sub-pixels 604 in each unique pair of sub-pixels 604 within the pixel 104 are determined. The first line of ratios from the calibration table 1204 is then selected (step 1316). The differences between the ratios stored in the calibration table 1204 and the corresponding ratios determined from the incident light are then calculated and saved to a difference matrix or table 1404 (see FIG. 14) (step 1320). In accordance with embodiments of the present disclosure, the differences for one signal ratio can be calculated as follows:

$$Δ \frac{PD 1}{PD 2} = Calibrated case \frac{PD 1}{PD 2} - Unknown case \frac{PD 1}{PD 2}$$

This calculating and storing of difference values in the difference matrix 1404 is repeated for each ratio represented in the calibration table for the selected wavelength.

At step 1324, a determination is made as to whether all of the lines (i.e. all of the wavelengths) represented within the calibration table 1204 have been considered. If lines remain to be considered, the next line of ratios (corresponding to the next wavelength) is selected from the calibration table 1204 (step 1328). The ratios measured for the unknown case are then compared to the ratios stored in the table for the next selected line of the calibration table 1204, corresponding to a next calibrated wavelength, to determine a next set of differences, which are then saved to the difference matrix (step 1320).

Once all of the lines (wavelengths) of values within the calibration table 1204 have been compared to the measured signal ratios, the line (wavelength) with the smallest row difference is identified, and the associated wavelength is assigned as the color of the light incident on the subject pixel 104 (step 1332). Where the difference for one line is zero, the wavelength associated with that line is identified as the color of the light incident on the subject pixel 104. Where no line has a difference of zero, a row difference for each line is calculated. The row with the smallest calculated row difference value is then selected as identifying the color of the light incident on the subject pixel. In accordance with embodiments of the present disclosure, the row difference is calculated as follows:

$$Difference Row Vector Module = \sqrt{{( Δ \frac{PD 1}{PD 2} )}^{2} + {( Δ \frac{PD 2}{PD 3} )}^{2} + ⋯ {( Δ \frac{PDn - 1}{PDn} )}^{2}}$$

After the color of the incident light has been determined, the sum of the signals from the sub-pixels 604 within the pixel is applied as the final pixel intensity signal (step 1336). As can be appreciated by one of skill in the art after consideration of the present disclose, this process can be performed for each pixel in the image sensor 100. As can further be appreciated by one of skill in the art after consideration of the present disclosure, where different calibration tables 1204 have been generated for different pixels 104, the process of color determination is performed in connection with the table that is applicable to the subject pixel 104. At step 1340, the assigned color and intensity can be recoded into RGB space for display. This process can be repeated for each of the pixels 104 in the image sensor 100.

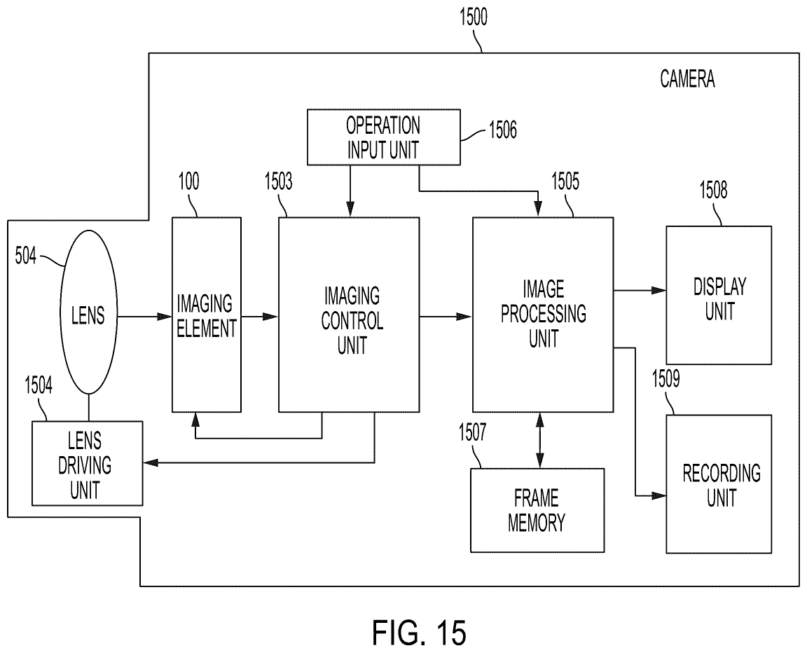

FIG. 15 is a block diagram illustrating a schematic configuration example of a camera 1500 that is an example of an imaging apparatus to which a system 500, and in particular a color image sensor 100, in accordance with embodiments of the present disclosure can be applied. As depicted in the figure, the camera 1500 includes an optical system or lens 504, an image sensor 100, an imaging control unit 1503, a lens driving unit 1504, an image processing unit 1505, an operation input unit 1506, a frame memory 1507, a display unit 1508, and a recording unit 1509.

The optical system 504 includes an objective lens of the camera 1500. The optical system 504 collects light from within a field of view of the camera 1500, which can encompass a scene containing an object. As can be appreciated by one of skill in the art after consideration of the present disclosure, the field of view is determined by various parameters, including a focal length of the lens, the size of the effective area of the image sensor 100, and the distance of the image sensor 100 from the lens. In addition to a lens, the optical system 504 can include other components, such as a variable aperture and a mechanical shutter. The optical system 504 directs the collected light to the image sensor 100 to form an image of the object on a light incident surface of the image sensor 100.

As discussed elsewhere herein, the image sensor 100 includes a plurality of pixels 104 disposed in an array 108. Moreover, the image sensor 100 can include a semiconductor element or substrate 112 in which the pixels 104 each include a number of sub-pixels 604 that are formed as photosensitive areas or photodiodes within the substrate 112. In addition, as also described elsewhere herein, each pixel 104 is associated with a set of diffraction features 524 formed in a diffraction layer 520 positioned between the optical system 504 and the sub-pixels 604. The photosensitive sites or sub-pixels 604 generate analog signals that are proportional to an amount of light incident thereon. These analog signals can be converted into digital signals in a circuit, such as a column signal processing circuit 120, included as part of the image sensor 100, or in a separate circuit or processor. As discussed herein the distribution of light amongst the sub-pixels 604 of a pixel 104 is dependent on the wavelength of the incident light. The digital signals can then be output.

The imaging control unit 1503 controls imaging operations of the image sensor 100 by generating and outputting control signals to the image sensor 100. Further, the imaging control unit 1503 can perform autofocus in the camera 1500 on the basis of image signals output from the image sensor 100. Here, “autofocus” is a system that detects the focus position of the optical system 504 and automatically adjusts the focus position. As this autofocus, a method in which an image plane phase difference is detected by phase difference pixels arranged in the image sensor 100 to detect a focus position (image plane phase difference autofocus) can be used. Further, a method in which a position at which the contrast of an image is highest is detected as a focus position (contrast autofocus) can also be applied. The imaging control unit 1503 adjusts the position of the lens 1001 through the lens driving unit 1504 on the basis of the detected focus position, to thereby perform autofocus. Note that, the imaging control unit 1503 can include, for example, a DSP (Digital Signal Processor) equipped with firmware.

The lens driving unit 1504 drives the optical system 504 on the basis of control of the imaging control unit 1503. The lens driving unit 1504 can drive the optical system 504 by changing the position of included lens elements using a built-in motor.

The image processing unit 1505 processes image signals generated by the image sensor 100. This processing includes, for example, assigning a color to light incident on a pixel 104 by determining ratios of signal strength between pairs of sub-pixels 604 included in the pixel 104, and determining an amplitude of the pixel signal 104 from the individual sub-pixel 604 signal intensities, as discussed elsewhere herein. In addition, this processing includes determining a color of light incident on a pixel 104 by comparing the observed ratios of signal strengths from pairs of sub-pixels 604 to calibrated ratios for those pairs stored in a calibration table 1204. As further examples, the image processing unit 1505 can generate conventional RGB and intensity values to enable image information collected by the camera 1500 to be output through the display unit 1508. The image processing unit 1505 can include, for example, a microcomputer equipped with firmware, and/or a processor that executes application programming, to implement processes for identifying color information in collected image information as described herein.

The operation input unit 1506 receives operation inputs from a user of the camera 1500. As the operation input unit 1506, for example, a push button or a touch panel can be used. An operation input received by the operation input unit 1506 is transmitted to the imaging control unit 1503 and the image processing unit 1505. After that, processing corresponding to the operation input, for example, the collection and processing of imaging an object or the like, is started.

The frame memory 1507 is a memory configured to store frames that are image signals for one screen or frame of image data. The frame memory 1507 is controlled by the image processing unit 1505 and holds frames in the course of image processing.

The display unit 1508 displays images processed by the image processing unit 1505. For example, a liquid crystal panel can be used as the display unit 1508.

The recording unit 1509 records images processed by the image processing unit 1505. As the recording unit 1509, for example, a memory card or a hard disk can be used.

An example of a camera 1500 to which embodiments of the present disclosure can be applied has been described above. The color image sensor 100 of the camera 1500 can be configured as described herein. Specifically, the image sensor 100 can diffract incident light across different light sensitive areas or sub-pixels 604 of a pixel 104, and can compare ratios of signals from pairs of the sub-pixels 604 to corresponding stored ratios for a number of different wavelengths, to identify a closest match, and thus a wavelength (color) of the incident light. Moreover, the color identification capabilities of the image sensor 100 can be described as hyperspectral, as wavelength identification is possible across the full range of wavelengths to which the sub-pixels are sensitive.

Note that, although a camera has been described as an example of an electronic apparatus, an image sensor 100 and other components, such as processors and memory for executing programming or instructions and for storing calibration information as described herein, can incorporated into other types of devices. Such devices include, but are not limited to, surveillance systems, automotive sensors, scientific instruments, medical instruments, etc.

As can be appreciated by one of skill in the art after consideration of the present disclosure, an image sensor 100 as disclosed herein can provide high color resolution over a wide spectral range. In addition, an image sensor 100 as disclosed herein can be produced using CMOS processes entirely. Implementations of an image sensor 100 or devices incorporating an image sensor 100 as disclosed herein can utilize calibration tables developed for each pixel 104 of the image sensor 100. Alternatively, calibration tables 1204 can be developed for each different pattern of diffraction features 524. In addition to providing calibration tables 1204 that are specific to particular pixels 104 and/or particular patterns of diffraction features 524, calibration tables 1204 can be developed for use in selected regions of the array 108.

The foregoing has been presented for purposes of illustration and description. Further, the description is not intended to limit the disclosed systems and methods to the forms disclosed herein. Consequently, variations and modifications commensurate with the above teachings, within the skill or knowledge of the relevant art, are within the scope of the present disclosure. The embodiments described hereinabove are further intended to explain the best mode presently known of practicing the disclosed systems and methods, and to enable others skilled in the art to utilize the disclosed systems and methods in such or in other embodiments and with various modifications required by the particular application or use. It is intended that the appended claims be construed to include alternative embodiments to the extent permitted by the prior art.

What is claimed is:

1. An image sensor, comprising:
a sensor substrate;
a pixel disposed in the sensor substrate, wherein the pixel includes a plurality of sub-pixels, and wherein a wavelength sensitivity of each sub-pixel within the pixel is the same; and
a diffraction layer disposed adjacent a light incident surface side of the sensor substrate, wherein the diffraction layer includes a set of transparent diffraction features.

2. The image sensor of claim 1, wherein the set of diffraction features is configured to focus incident light onto the pixel.

3. The image sensor of claim 1, wherein the set of diffraction features is formed in a layer of material having a refractive index that is lower than the refractive index of the plurality of diffraction features.

4. The image sensor of claim 1, wherein the set of diffraction features includes a plurality of diffraction elements.

5. The image sensor of claim 4, wherein at least some of the diffraction features are formed from a first material, and wherein others of the diffraction features are formed from a second material.

6. The image sensor of claim 4, wherein the set of diffraction features includes a central element and a plurality of radially disposed linear elements.

7. The image sensor of claim 6, wherein the set of diffraction features are disposed asymmetrically relative to a center of the pixel.

8. The image sensor of claim 6, wherein the diffraction features are disposed so as to provide a higher effective index of refraction towards a center of the set of diffraction features than towards a periphery of the diffraction features.

9. The image sensor of claim 1, wherein a plurality of pixels, each including a plurality of sub-pixels, is disposed in the sensor substrate, wherein the plurality of pixels are arranged in a two-dimensional array, and wherein the diffraction layer includes a set of transparent diffraction features for each pixel in the plurality of pixels.

10. The image sensor of claim 9, wherein a pattern of the diffraction features for a first pixel in the plurality of pixels is different than a pattern of the diffraction features for a second pixel in the plurality of pixels.

11. The image sensor of claim 10, wherein the first pixel is nearer a center of the array than the second pixel.

12. The image sensor of claim 1, further comprising:
an antireflective coating, wherein the antireflective coating is between the sensor substrate and the diffraction layer.

13. The image sensor of claim 1, wherein a thickness of the diffraction layer is less than 500 nm.

14. An imaging device, comprising:
an image sensor, including:
a sensor substrate;
a plurality of pixels formed in the sensor substrate, wherein each pixel in the plurality of pixels includes a plurality of sub-pixels, and wherein, for a given pixel in the plurality of pixels, a wavelength sensitivity of each of the sub-pixels is the same; and
a diffraction layer disclosed adjacent a light incident surface side of the sensor substrate, wherein the diffraction layer includes a set of transparent diffraction features for each pixel in the plurality of pixels.

15. The imaging device of claim 14, further comprising:
an imaging lens, wherein light collected by the imaging lens is incident on the image sensor, and wherein the transparent diffraction features focus and diffract the incident light onto the sub-pixels of the respective pixels.

16. The imaging device of claim 15, further comprising:
a processor, wherein the processor executes application programming, wherein the application programming determines a color of light incident on a selected pixel from ratios of a relative strength of a signal generated at each unique pair of sub-pixels of the selected pixel in response to the light incident on the selected pixel.

17. The imaging device of claim 16, further comprising:
data storage, wherein the data storage stores ratios of signal strengths between each of the sub-pixels in the selected pixel for different wavelengths of incident light, and wherein different combinations of signal strength ratios identify different wavelengths of incident light.

18. A method, comprising:
receiving light at an image sensor having a plurality of pixels;
for each pixel in the plurality of pixels, diffracting the received light onto a plurality of sub-pixels, wherein for each pixel the received light is diffracted by a different set of transparent diffraction features;
for each pixel in the plurality of pixels, determining a ratio of a signal strength generated by the sub-pixels in each unique pair of the sub-pixels; and
determining a color of the received light at each pixel in the plurality of pixels from the determined relative signal strength at each of the sub-pixels.

19. The method of claim 18, wherein determining a color of the received light at each pixel includes identifying a color associated with a nearest set of sub-pixel signal strength ratios.

20. The method of claim 18, further comprising:
determining an intensity of the received light at each pixel by calculating a sum of the signal strength at each included sub-pixel.
